(19) United States
(12) Patent Application Publication
(10) Pub. No.: US 2024/0319832 A1
(43) Pub. Date: Sep. 26, 2024

(54) Touch Layer, Touch Display Apparatus, and Manufacturing Method for Touch Layer

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Yang Zeng, Beijing (CN); Shun Zhang, Beijing (CN); Tianci Chen, Beijing (CN); Chang Luo, Beijing (CN); Yi Zhang, Beijing (CN)

(21) Appl. No.: 18/578,159

(22) PCT Filed: May 19, 2023
(86) PCT No.: PCT/CN2023/095329

§ 371 Date: Jan. 10, 2024

(30) Foreign Application Priority Data
Jun. 17, 2022 (CN) 202210688848.2

(51) Int. Cl. G06F 3/044; G06F 3/041; H10K 59/12; H10K 59/122; H10K 59/40

(52) U.S. Cl. CPC G06F 3/0446; G06F 3/0412; G06F 3/0443; H10K 59/1201; H10K 59/122; H10K 59/40; G06F 2203/04103; G06F 2203/04111

(57) ABSTRACT

A touch layer includes a first sensing electrode, a second sensing electrode and a conductive pattern group. The first sensing electrode includes first electrode blocks. The second sensing electrode is crosswise with and insulated from the first sensing electrode, including second electrode blocks. A first electrode block includes a first body and first finger portions protruding from the first body. A second electrode block has notches located at its edge, and a first finger portion extends into a notch. The conductive pattern group includes conductive patterns distributed spaced apart along a demarcation path segment, and the demarcation path segment is a portion, between root endpoints of two adjacent first finger portions at a same side, of a demarcation line between the first and second electrode blocks. A conductive pattern is jointly surrounded by the first and second electrode blocks, and is insulated from the first and second electrode blocks.

### CROSS-REFERENCE TO RELATED APPLICATIONS

This application is the United States national phase of International Patent Application No. PCT/CN2023/095329 filed May 19, 2023, and claims priority to Chinese Patent Application No. 202210688848.2 filed Jun. 17, 2022, the disclosures of which are hereby incorporated by reference in their entireties.

### BACKGROUND OF THE INVENTION

### Field of the Invention

The present disclosure relates to the field of display technologies, and in particular, to a touch layer, a touch display apparatus, and a method for manufacturing a touch layer.

### Description of Related Art

A touch structure is of a capacitive type, a resistive type, an infrared type or a surface acoustic wave type. The capacitive type touch structure works by utilizing a current induction phenomenon of a human body, supports multi-point touch, and has advantages such as wear-resistant, long service life, and low power consumption, so it has been developed faster.

Capacitive type touch structures are classified into mutual capacitive type touch structures and self-capacitive type touch structures. A mutual capacitive type touch structure may include two groups of electrode strips that are arranged crosswise (e.g., including a group of touch scanning electrode strips and a group of touch sensing electrode strips), and a plurality of capacitors are formed near positions where the two groups of electrode strips cross each other. When a finger touches a screen, capacitances of some capacitors near a touch point are affected. Based on the changes in these capacitances, the touch position can be determined.

### SUMMARY OF THE INVENTION

In an aspect, a touch layer is provided. The touch layer includes a first sensing electrode, a second sensing electrode and a conductive pattern group. The first sensing electrode includes a plurality of first electrode blocks electrically connected to each other. The second sensing electrode is arranged crosswise with the first sensing electrode and insulated from each other, including a plurality of second electrode blocks electrically connected to each other. A first electrode block includes a first body and a plurality of first finger portions protruding from the first body, a second electrode block has a plurality of notches located at an edge thereof, and a first finger portion extends into a notch.

The conductive pattern group includes a plurality of conductive patterns distributed spaced apart along a demarcation path segment, and the demarcation path segment is a portion, between root endpoints of two adjacent first finger portions at a same side, of a demarcation line between the first electrode block and the second electrode block. A conductive pattern is jointly surrounded by the first electrode block and the second electrode block, and is insulated from both the first electrode block and the second electrode block.

In some embodiments, the conductive pattern is formed by a plurality of conductive lines crossing each other; and the conductive pattern has one intersection node.

Exemplarily, the conductive pattern has at least two intersection nodes distributed along the demarcation path segment.

In some embodiments, in the conductive pattern group, a total length of the conductive patterns is less than or equal to half a length of the demarcation path segment.

In some embodiments, the conductive pattern group includes at least one first conductive pattern, and the first conductive pattern is one of the conductive patterns; and the first electrode block has a grid structure, and at least one first square point vacancy is provided along the demarcation path segment; and the first conductive pattern is disposed at the first square point vacancy.

In some embodiments, the conductive pattern group includes at least one second conductive pattern, and the second conductive pattern is one of the conductive patterns; and the second electrode block has a grid structure, and at least one second grid point vacancy is provided along the demarcation path segment; and the second conductive pattern is disposed at the second grid point vacancy.

In some embodiments, in the conductive pattern group, the first conductive pattern and the second conductive pattern are same in number.

In some embodiments, the demarcation path segment includes: a first section and a second section that surround the first finger portion and are opposite along a width direction of the first finger portion; and the conductive pattern group includes M1 first conductive patterns distributed along the first section, and M2 second conductive patterns distributed along the second section, where M1 and M2 are both greater than or equal to 1.

In some embodiments, M1 and M2 are equal.

In some embodiments, at least one of the M1 first conductive patterns and at least one of the M2 second conductive patterns are opposite to each other along the width direction of the first finger portion.

In some embodiments, the conductive pattern group further includes M3 second conductive patterns distributed along the first section, and M4 first conductive patterns distributed along the second section, where M3 and M4 are both greater than or equal to 1.

In some embodiments, M3 and M4 are equal.

In some embodiments, at least one of the M3 second conductive patterns is opposite to at least one of the M4 first conductive patterns along the width direction of the first finger portion.

In some embodiments, the demarcation path segment includes a third section surrounding the first finger portion and extending substantially along a width direction of the first finger potion, and a fourth section located between the two adjacent first finger potions. The conductive pattern group further includes N1 first conductive patterns distributed along the third section and N2 second conductive patterns distributed along the fourth section, N1 and N2 are both greater than or equal to 1.

Exemplarily, the demarcation path segment includes a third section surrounding the first finger portion and extending substantially along a width direction of the first finger potion, and a fourth section located between the two adjacent first finger potions. The conductive pattern group further includes Q1 second conductive patterns distributed along the third section and Q2 first conductive patterns distributed along the fourth section, Q1 and Q2 are both greater than or equal to 1.

Exemplarily, the demarcation path segment includes a third section surrounding the first finger portion and extending substantially along a width direction of the first finger potion, and a fourth section located between the two adjacent first finger potions. The conductive pattern group further includes N1 first conductive patterns distributed along the third section and N2 second conductive patterns distributed along the fourth section, N1 and N2 are both greater than or equal to 1. The conductive pattern group further includes Q1 second conductive patterns distributed along the third section and Q2 first conductive patterns distributed along the fourth section, Q1 and Q2 are both greater than or equal to 1.

In some embodiments, N1 and N2 are equal, and Q1 and Q2 are equal.

In some embodiments, in a case where the conductive pattern group includes the N1 first conductive patterns and the N2 second conductive patterns, at least one of the N1 first conductive patterns is distributed at an end of the third section; and at least one of the N2 second conductive patterns is distributed at an end of the fourth section.

In some embodiments, in a case where the conductive pattern group includes the Q1 second conductive patterns and the Q2 first conductive patterns, at least one of the Q1 second conductive patterns is distributed at an end of the third section; and at least one of the Q2 first conductive patterns is distributed at an end of the fourth section.

In some embodiments, the first finger portion includes a first finger segment and a second finger segment, and the first finger segment is farther from the first body than the second finger segment; and a width of the first finger segment is less than a width of the second finger segment.

In some embodiments, a portion of the demarcation path segment surrounding the first finger segment is provided with at least one conductive pattern distributed.

In some embodiments, a portion of the demarcation path segment surrounding the second finger segment is provided with at least one conductive pattern.

In some embodiments, a portion of the demarcation path segment surrounding the first finger segment is provided with at least one conductive pattern distributed, and a portion of the demarcation path segment surrounding the second finger segment is provided with at least one conductive pattern.

In some embodiments, the first finger portion has a grid structure, and along a width direction of the first finger portion, areas of two adjacent squares in the grid structure are not equal.

Exemplarily, the first finger portion has a grid structure, and along an extension direction of the first finger portion, areas of two adjacent squares in the grid structure are not equal.

Exemplarily, the first finger portion has a grid structure, and along a width direction of the first finger portion, areas of two adjacent squares in the grid structure are not equal; and along an extension direction of the first finger portion, areas of two adjacent squares in the grid structure are not equal.

In some embodiments, the first finger portion has a grid structure. The first finger portion has a first break, and the first break communicates two adjacent squares in the grid structure in a width direction of the first finger portion.

Exemplarily, the first finger portion has a grid structure. The first finger portion has a second break, and the second break communicates two adjacent squares in the grid structure in an extension direction of the first finger portion.

Exemplarily, the first finger portion has a grid structure. The first finger portion has a first break and a second break. The first break communicates two adjacent squares in the grid structure in a width direction of the first finger portion, and the second break communicates two adjacent squares in the grid structure in an extension direction of the first finger portion.

In some embodiments, the first body is provided therein with a plurality of first dummy portions, and the first dummy portions are electrically insulated from the first electrode block.

Exemplarily, the second electrode block is provided therein with a plurality of second dummy portions, and the second dummy portions are electrically insulated from the second electrode block.

Exemplarily, the first body is provided therein with a plurality of first dummy portions, and the first dummy portions are electrically insulated from the first electrode block. The second electrode block is provided therein with a plurality of second dummy portions, and the second dummy portions are electrically insulated from the second electrode block.

In another aspect, a touch display apparatus is provided. The touch display apparatus includes a plurality of sub-pixels, a pixel define layer, and the touch layer according to any one of the above embodiments. The pixel define layer has a plurality of openings to define positions of the plurality of sub-pixels. The first electrode blocks, the second electrode blocks and the conductive pattern group form a grid structure, and the grid structure includes a plurality of squares. The plurality of squares include at least one first square, and the first square is jointly surrounded by the first electrode block, the second electrode block, and the conductive pattern in the conductive pattern group, and the first square is directly opposite to an opening along a thickness direction of the touch layer.

In yet another aspect, a method for manufacturing a touch layer is provided. The manufacturing method includes: forming a first sensing electrode, a second sensing electrode and a conductive pattern group. The first sensing electrode and a second sensing electrode are arranged crosswise and insulated from each other. The first sensing electrode includes a plurality of first electrode blocks electrically connected to each other. The second sensing electrode includes a plurality of second electrode blocks electrically connected to each other. A first electrode block includes a first body and a plurality of first finger portions protruding from the first body. A second electrode block includes a plurality of notches located at an edge thereof, and a first finger portion extends into a notch. The conductive pattern group includes a plurality of conductive patterns distributed spaced apart along a demarcation path segment, the demarcation path segment is a portion, between root endpoints of two adjacent first finger portions at a same side, of a demarcation line between the first electrode block and the second electrode block; and a conductive pattern is jointly surrounded by the first electrode block and the second electrode block, and is insulated from both the first electrode block and the second electrode block.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1A is a side view of a touch display apparatus in accordance with some embodiments;

FIG. 1B is a structural diagram of the display apparatus of FIG. 1A;

FIG. 1C is a top view of FIG. 1A;

FIG. 2 is an enlarged view of the region D1 in FIG. 1C;

FIG. 3 is an enlarged view of the region D2 in FIG. 2;

FIG. 4 is a structural diagram of a first electrode block in FIG. 2;

FIG. 5 is a structural diagram of a second electrode block in FIG. 2;

FIG. 6A is an enlarged view of the region D3 in FIG. 3;

FIG. 6B is an alternative enlarged view of the region D3 in FIG. 3;

FIG. 6C is another alternative enlarged view of the region D3 in FIG. 3;

FIG. 7 is a simulation data table of some embodiments;

FIG. 8 is yet another alternative enlarged view of the region D3 in FIG. 3;

FIG. 9 is yet another alternative enlarged view of the region D3 in FIG. 3;

FIG. 10 is yet another alternative enlarged view of the region D3 in FIG. 3;

FIG. 11 is yet another alternative enlarged view of the region D3 in FIG. 3;

FIG. 12 is yet another alternative enlarged view of the region D3 in FIG. 3;

FIG. 13 is yet another alternative enlarged view of the region D3 in FIG. 3;

FIG. 14 is yet another alternative enlarged view of the region D3 in FIG. 3;

FIG. 15 is yet another alternative enlarged view of the region D3 in FIG. 3;

FIG. 16 is yet another alternative enlarged view of the region D3 in FIG. 3;

FIG. 17 is yet another alternative enlarged view of the region D3 in FIG. 3;

FIG. 18A is a sectional view taken along the line A1-A2 in FIG. 3;

FIG. 18B is an exploded view of FIG. 18A;

FIG. 19A is another sectional view taken along the line A1-A2 in FIG. 3;

FIG. 19B is an exploded view of FIG. 19A;

FIG. 20A is yet another sectional view taken along the line A1-A2 in FIG. 3;

FIG. 20B is an exploded view of FIG. 20A;

FIG. 21A is yet another sectional view taken along the line A1-A2 in FIG. 3; and

FIG. 21B is an exploded view of FIG. 21A.

### DESCRIPTION OF THE INVENTION

The technical solutions in embodiments of the present disclosure will be described clearly and completely with reference to the accompanying drawings; obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a plurality of/the plurality of” means two or more unless otherwise specified.

Some embodiments may be described using the terms “coupled”, “connected” and their derivatives. For example, the term “connected” may be used in the description of some embodiments to indicate that two or more components are in direct physical or electrical contact with each other. As another example, the term “connected” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

The term such as “about”, “substantially” or “approximately” as used herein includes a stated value and an average value within an acceptable range of deviation of a particular value determined by a person of ordinary skilled in the art, considering measurement in question and errors associated with measurement of a particular quantity (i.e., limitations of a measurement system).

As used herein, the term such as “parallel”, “perpendicular” or “equal” includes a stated condition and a condition similar to the stated condition, a range of the similar condition is within an acceptable range of deviation, and the acceptable range of deviation is determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the region in a device, and are not intended to limit the scope of the exemplary embodiments.

Embodiments of the present disclosure provide a touch display apparatus. The touch display apparatus may be a product having a touch function and an image display function. For example, the touch display apparatus may be a display, a television, a personal computer, a notebook computer, a billboard, a digital photo frame, and a laser printer having a display function, a telephone, a mobile phone, a digital camera, an electronic picture screen, a portable camcorder, a viewfinder, a monitor, a navigator, a vehicle, a large-area wall, an information search device (e.g., a business search device in a department such as an electronic government, a bank, a hospital or an electric power department), a vehicle-mounted display or the like, which has a touch function.

As another example, the touch display apparatus may be a touch display panel (which may also be referred to as a touch display screen).

As another example, the touch display apparatus may include other electronic devices in addition to the touch display panel, such as a touch chip, a display driver integrated circuit (DDIC), and a motherboard. The touch chip is coupled to the touch display panel and configured to, based on touch signals provided by the touch display panel, determine a touch position (e.g., touch coordinates). The motherboard is coupled to the DDIC and configured to, based on the touch position determined by the touch chip, output corresponding image data to the DDIC. The DDIC is coupled to the touch display panel and configured to, based on the received image data, drive the touch display panel to display a corresponding image.

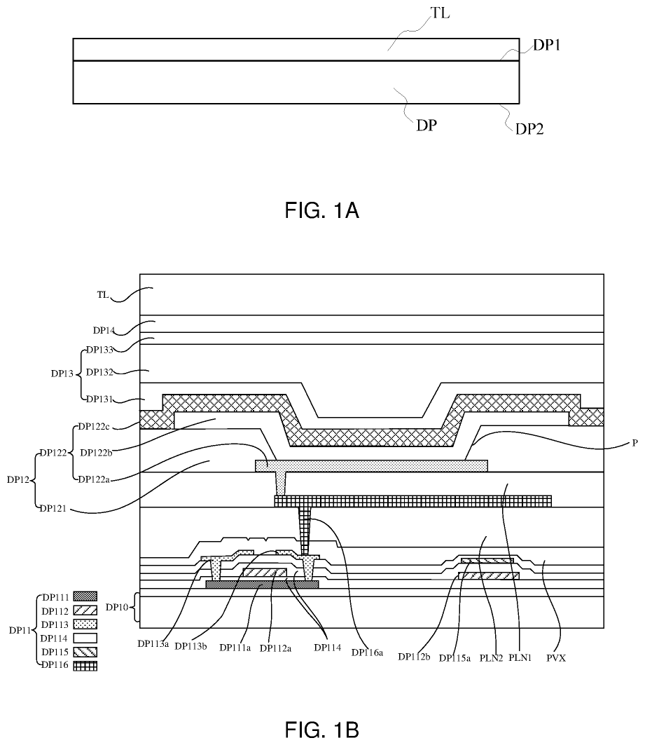

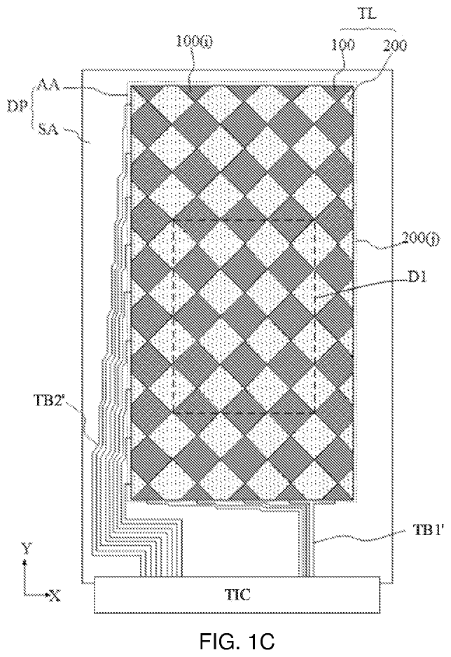

FIG. 1A is a side view of a touch display apparatus in accordance with some embodiments. FIG. 1B is a structural diagram of the display apparatus of FIG. 1A. Referring to FIG. 1A and FIG. 1B, the touch display apparatus (e.g., the touch display panel) includes a display panel DP and a touch layer TL. An assembly constituted by the display panel DP and the touch layer TL may also be referred to as the touch display panel.

Referring to FIG. 1A, the display panel DP is a screen having a display function, and may be coupled to the DDIC as described above, and is configured to receive data signals sent by the DDIC and display a corresponding image. For example, the display panel DP may be an organic light-emitting diode (OLED) display panel, a quantum dot light-emitting diode (QLED) display panel, a tiny light-emitting diode (including a mini LED or a micro LED) display panel, or the like.

The display panel DP has a display surface DP1 and a non-display surface DP2 that are opposite in a thickness direction of the display panel DP. Users can view images facing the display surface DP1 of the display panel DP. That is, a side of the display surface DP1 away from the non-display surface DP2 of the display panel DP is a side for the users to view images, and this side is hereinafter referred to as a display side of the display panel DP.

With continued reference to FIG. 1A, the touch layer TL is configured to provide touch signals, and the touch signals may reflect a touch position of a user on the display panel DP. The touch layer TL may be coupled to the touch chip above to provide the touch signals to the touch chip.

In some possible implementations, the touch layer TL may be located on the display side of the display panel DP. The touch layer TL may be a component independent of the display panel DP. Exemplarily, the display panel DP and the touch layer TL are formed separately and then bonded together by an adhesive such as an optical adhesive.

The touch layer TL may also be a structure integrated on the display panel DP. Exemplarily, using the display panel DP as a substrate, the touch layer TL is formed on the display surface DP1 of the display panel DP. In this case, the touch layer TL is in direct contact with the display surface DP1 of the display panel DP, or other functional layers may be provided between the touch layer TL and the display surface DP1 of the display panel DP.

In some other possible implementations, the touch layer may also be located inside the display panel. Exemplarily, the display panel includes a first substrate and a second substrate that are disposed oppositely, and the touch layer may be located between the first substrate and the second substrate.

The display panel DP may include a plurality of sub-pixels. Each sub-pixel includes a pixel driving circuit and a light-emitting device coupled to each other, and the pixel driving circuit is configured to drive the light-emitting device to emit light. The pixel driving circuit may include a plurality of electronic device elements such as a plurality of transistors and a capacitor. For example, each pixel driving circuit may include three transistors and one capacitor to form 3T1C (i.e., one driving transistor, two switching transistors, and one capacitor). Alternatively, the pixel driving circuit may include more than three transistors and at least one capacitor, such as 4T1C (i.e., one driving transistor, three switching transistors, and one capacitor), 5T1C (i.e., one driving transistor, four switching transistors, and one capacitor), or 7T2C (i.e., one driving transistor, six switching transistors, and two capacitors), or the like. Among them, the transistor may be a field effect transistor (metal oxide semiconductor (MOS)), or other switching device with the same characteristics, where the field effect transistor may be a thin film transistor (TFT). The light-emitting device may be OLED or QLED.

In order to realize a structure of the above sub-pixel, exemplarily, with continued reference to FIG. 1B, the display panel DP includes: a substrate DP10, a pixel driving circuit layer DP11 and a light-emitting device layer DP12 that are stacked in sequence.

A structure of the substrate DP10 may be selected and set according to actual needs.

For example, the substrate DP10 may be a rigid substrate. The rigid substrate may include, for example, a glass substrate or a polymethyl methacrylate (PMMA) substrate. In this case, the above display panel DP may be a rigid display panel.

As another example, the substrate DP10 may be a flexible substrate. The flexible substrate may include, for example, a polyethylene terephthalate (PET) substrate, a polyethylene naphthalate (PEN) substrate or a polyimide (PI) substrate. In this case, the display panel 100 may be a flexible display panel.

The substrate DP10 may have a one-layer structure or a multi-layer structure. For example, the substrate may include at least one flexible substrate and at least one buffer layer, and the flexible substrate and the buffer layer are alternately stacked.

Exemplarily, with continued reference to FIG. 1B, the pixel driving circuit layer DP11 may include: an active pattern layer DP111, a first conductive pattern layer DP112, and a second conductive pattern layer DP113 that are stacked in sequence; and may further include insulating layers DP114 spacing these pattern layers. These layers may form a plurality of pixel driving circuits.

In the embodiments of the present disclosure, the “pattern layer” may be a layer structure including specific patterns, which is formed by a patterning process on at least one film layer formed by the same film forming process. Depending on different specific patterns, the patterning process may include several coating, exposure, development or etching processes, and the specific patterns in the formed layer structure may be continuous or discontinuous, and these specific patterns may also be at different heights (or have different thicknesses). The “conductive pattern layer” is a pattern layer with conductive properties, which is made of a conductive material. Exemplarily, the “conductive pattern layer” is made of a transparent conductive material. For example, the transparent conductive material may be selected from at least one of indium tin oxide (ITO), aluminum doped zinc oxide (AZO), or the like, which is both electrically conductive and has a high light transmittance within a range of the visible light. The “conductive pattern layer” may also be made of a metal material. For example, the metal material may be at least one of aluminum (Al), silver (Ag), copper (Cu), chromium (Cr), or the like.

The first conductive pattern layer DP112 includes a plurality of gate electrodes DP112a; the active pattern layer DP111 includes a plurality of active patterns DP111a; and the second conductive pattern layer DP113 includes a plurality of source electrodes DP113a and a plurality of drain electrodes DP113b. Among them, an active pattern DP111a, a gate electrode DP112a, a source electrode DP113a and a drain electrode DP113b that are corresponding may form a transistor, and multiple transistors may form a pixel driving circuit.

In addition, the pixel driving circuit layer may further include a third conductive pattern layer DP115 located between the first conductive pattern layer DP112 and the second conductive pattern layer DP113. For example, the first conductive pattern layer DP112 further includes first capacitor electrode plates DP112b, and the third conductive pattern layer DP115 further includes second capacitor electrode plates DP115a; and a first capacitor electrode plate DP112b and a second capacitor electrode plate DP115a are arranged oppositely to form a capacitor in a pixel driving circuits. In some other examples, the second capacitor electrode plates DP115a may also be included in the second conductive pattern layer DP113.

The light-emitting device layer DP12 may include a pixel define layer DP121 and a plurality of light-emitting devices DP122. The pixel define layer DP121 has a plurality of openings P, and an opening P defines a position of a light-emitting device DP122.

Exemplarily, the light-emitting device DP122 includes a first electrode (e.g., an anode) DP122a, a light-emitting layer DP122b, and a second electrode (e.g., a cathode) DP122c disposed in sequence.

For example, a structure of the first electrode DP122a may be a composite structure composed of a transparent conductive oxide film/a metal film/a transparent conductive oxide film stacked in sequence. Here, a material of the transparent conductive oxide film is, for example, any one of ITO and IZO, and a material of the metal film is, for example, any one of gold (Au), silver (Ag), nickel (Ni), and platinum (Pt).

As another example, the structure of the first electrode DP122a may also be a single-layer structure, and a material of the single-layer structure may be any one of ITO, IZO, Au, Ag, Ni, and Pt.

Exemplarily, with continued reference to FIG. 1B, among the plurality of openings P of the pixel define layer DP121, an opening P exposes at least a portion (portion or all) of a first electrode DP122a. At least a portion of a light-emitting layer DP122b is located in an opening P and forms an electrical connection with a corresponding first electrode DP122a.

Here, the arrangement manner of the light-emitting layer DP122b is related to the preparation process of the light-emitting layer DP122b. For example, in a case where the light-emitting layer DP122b is formed using a vapor deposition process, a portion of the light-emitting layer DP122b may be located in a corresponding opening P, and the other portion overlaps the pixel define layer DP121 around the opening P. Of course, the entire light-emitting layer DP122b may also be located in the corresponding opening P. In a case where the light-emitting layer DP122b is formed using inkjet printing technology, the entire light-emitting layer DP122b may be located within the corresponding opening P.

Exemplarily, with continued reference to FIG. 1B, the second electrode DP122c is located on a side of the pixel define layer DP121 away from the substrate DP10. Second electrodes DP122c of all the light-emitting devices may be electrically connected to each other in an integral structure.

For example, a material of the second electrode DP122c may be any one of aluminum (Al), silver (Ag), and magnesium (Mg), or any one of magnesium-silver alloy and aluminum-lithium alloy.

Of course, the light-emitting device layer DP12 may further include at least one of a hole injection layer, a hole transport layer, and an electron blocking layer disposed between the first electrode DP122a and the light-emitting layer DP122b, and at least one of an electron injection layer, an electron transport layer, and a hole blocking layer disposed between the second electrode DP122c and the light-emitting layer DP122b.

In some possible implementations, with continued reference to FIG. 1B, the display panel DP may further include: a first planarization layer PLN1 located between the light-emitting device layer DP12 and the pixel driving circuit layer DP11, and the first planarization layer PLN1 is in direct contact with the light-emitting device layer DP12.

With continued reference to FIG. 1B, in a case where the display panel further includes the first planarization layer PLN1, first electrodes DP122a of light-emitting devices DP122 are disposed on a surface of the first planarization layer PLN1 away from the substrate DP10. A first electrode DP122a of a light-emitting device layer DP12 may be electrically connected to a pixel driving circuit through the first planarization layer PLN1.

In some possible implementations, with continued reference to FIG. 1B, the display panel DP may further include: a fourth conductive pattern layer DP116 located between the first planarization layer PLN1 and the pixel driving circuit layer DP11. The fourth conductive pattern layer DP116 may include a plurality of connection portions DP116a.

In a case where the pixel driving circuit layer DP11 further includes the fourth conductive pattern layer DP116, a first electrode DP122a of a light-emitting device DP122 may be electrically connected to a pixel driving circuit through a connection portion DP116a.

In some possible implementations, with continued reference to FIG. 1B, the display panel DP may further include: a second planarization layer PLN2 and a passivation layer PVX that are located on a side of the pixel driving circuit layer DP11 away from the substrate DP10. The second planarization layer PLN2 may be made of an organic insulating material. The passivation layer PVX may be made of an inorganic insulating material.

In some possible implementations, with continued reference to FIG. 1B, the display panel DP further includes: an encapsulation layer DP13 disposed on a side of the light-emitting device layer DP12 away from the substrate DP10.

Exemplarily, with continued reference to FIG. 1B, the encapsulation layer DP13 includes a first inorganic insulating layer DP131, an organic insulating layer DP132, and a second inorganic insulating layer DP133 that are stacked in sequence.

Exemplarily, the first inorganic insulating layer DP131 and the second inorganic insulating layer DP133 may be made of an inorganic material of nitride, oxide, oxynitride, nitrate, carbide or any combination thereof. The organic insulating layer DP132 may be made of acrylic, hexamethyldisiloxane, polyacrylate, polycarbonate, polystyrene or other materials.

With continued reference to FIG. 1B, exemplarily, the above encapsulation layer DP13 may serve as the display surface of the display panel DP. For example, the touch layer TL may be formed on the encapsulation layer DP13 through a process such as photolithography. As another example, the display apparatus may further include: a buffer layer DP14, and the buffer layer DP14 is disposed on a side of the encapsulation layer DP13 away from the substrate DP10. The touch layer TL is disposed on the buffer layer DP14 and may be in contact with the buffer layer DP14.

Referring to FIG. 1C, the display panel DP has a display area AA and non-display area SA. The display area AA is an area of the display panel DP for displaying images, and the non-display area SA is an area of the display panel DP other than the display area AA. The non-display area SA may be located at at least one side (e.g., one side or more sides) of the display area AA. For example, the non-display area SA may be disposed around the display area AA.

Exemplarily, the display area AA may be in a shape of a rectangle, or may be in another shape similar to the rectangle such as a rectangle with rounded corners. Based on this, the display area AA has two sides intersecting (e.g., being perpendicular to) each other. For convenience of description, a rectangular coordinate system is established by taking extension directions of the two sides as an X-axis and a Y-axis, respectively.

With continued reference to FIG. 1C, the touch layer TL may include: a group of first sensing electrodes 100 (including N first sensing electrodes 100, where N≥1; for example, N=1, or for example, N≥2) and a group of second sensing electrodes 200 (including M second sensing electrodes 200, where M≥1; for example, M=1, or for example M>2), in which the group of first sensing electrodes 100 and the group of second sensing electrodes 200 cross each other and are insulated from each other. Exemplarily, in a case where the touch layer TL includes a plurality of first sensing electrodes 100, the plurality of first sensing electrodes 100 may be arranged at intervals along a first direction X; and in a case where the touch layer TL further includes a plurality of second sensing electrodes 200, the plurality of second sensing electrodes 200 may be arranged at intervals along a second direction Y. The second direction Y and the first direction X intersect each other, e.g., are perpendicular to each other. For example, the second direction Y is a direction indicated by the Y-axis, and the first direction X is a direction indicated by the X-axis. Furthermore, the second direction Y and the first direction X illustrated in FIG. 1C may be interchangeable.

For example, the first sensing electrodes 100 serve as touch scanning electrode strips (TX), and the second sensing electrodes 200 serve as touch sensing electrode strips (RX). As another example, the first sensing electrodes 100 serve as touch sensing electrode strips, and the second sensing electrodes 200 serve as touch scanning electrode strips.

The group of first sensing electrodes 100 and the group of second sensing electrodes 200 may both correspond to the display area AA of the display panel DP, which means that for each first sensing electrode 100 and each second sensing electrode 200, an orthographic projection of each of the two on the display panel DP is at least partially (i.e., partially or completely) located in the display area AA, so that the touch layer TL can sense a touch operation corresponding to the display area AA.

The phrase “an orthographic projection of A on B” herein means a projection of A on B in a direction perpendicular to a plane where B is located. For example, an orthographic projection of a first sensing electrode 100 on the display panel DP refers to a projection of the first sensing electrode 100 on the display panel DP in a thickness direction of the display panel DP.

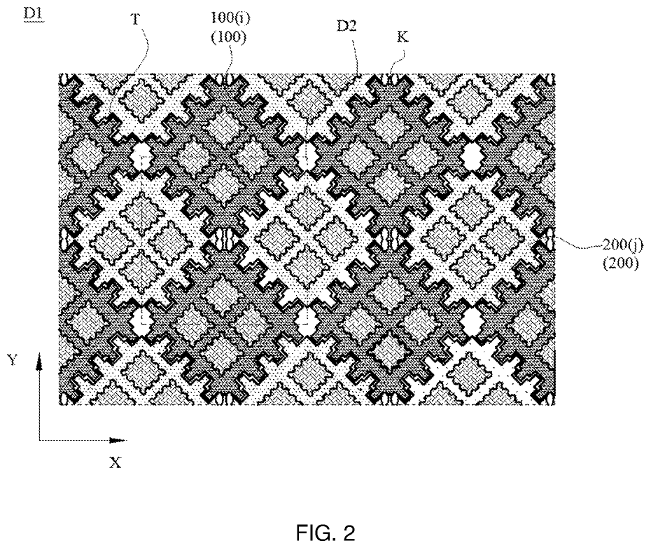

In addition, referring to FIG. 1C, the group of first sensing electrode 100 may be coupled to the touch chip (i.e., a touch integrated circuit (TIC)) through a group of first leads TB1′, and the group of second sensing electrode 200 may be coupled to the touch chip (TIC) through a group of second leads TB2′. The group of first leads TB1′ and the group of second leads TB2′ may be included in the touch layer TL or included in the display panel DP. The group of first sensing electrodes 100 and the group of second sensing electrodes 200 may be divided into a plurality of capacitor units T (shown in FIG. 2), and each capacitor unit may include a cross position (i.e., a cross position of a first sensing electrode and a second sensing electrode). The shape and structure of each capacitor unit may be approximately the same, so the capacitor unit may be referred to as a repeating unit. In a capacitor unit, a mutual capacitance value of the first sensing electrode 100 and the second sensing electrode 200 without touch (for example, when a finger does not touch the touch display apparatus) is denoted as Cm. In a capacitor unit, a difference between the mutual capacitance values of the first sensing electrode 100 and the second sensing electrode 200 before and after touch (may also be referred to as a capacitance difference or a signal quantity) is denoted as ΔCm, i.e., in the capacitor unit, a difference between Cm and the mutual capacitance value of the first sensing electrode 100 and the second sensing electrode 200 when touched by a finger.

A touch process of the touch display apparatus can meet the following conditions: only if ΔCm/Cm of a capacitor unit is relatively large, the touch control chip (TIC) can accurately recognize the signal change before and after a touch, and then determine whether the touch occurs. However, in a conventional solution, the signal amount ΔCm is relatively small, and the ΔCm/Cm is also relatively small, so there will be a situation where the signal change before and after the touch is not accurately recognized.

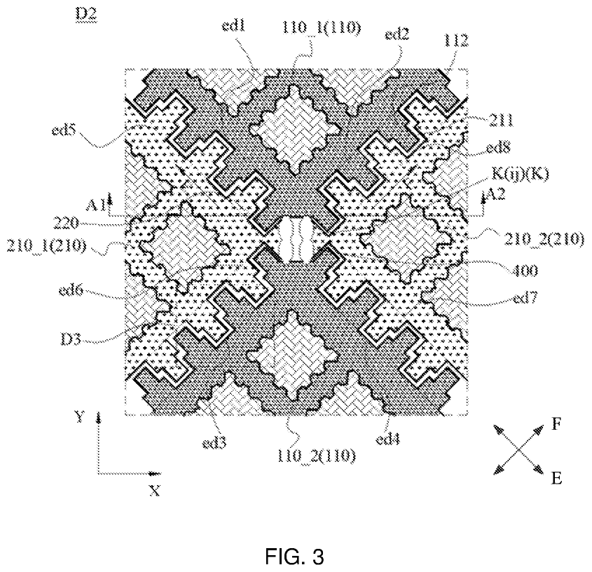

FIG. 2 is an enlarged view of the region D1 in FIG. 1C. FIG. 3 is an enlarged view of the region D2 in FIG. 2. Referring to FIG. 2, some embodiments of the present disclosure provide a touch layer TL. A first sensing electrode 100 of the touch layer TL includes a plurality of first electrode blocks 110 electrically connected to each other. Exemplarily, the plurality of first electrode blocks 110 are arranged along the second direction Y, and these first electrode blocks 110 are arranged in a column to form a first sensing electrode 100. If the touch layer TL needs to be provided therein with N first sensing electrodes 100 (shown in FIG. 1C), any one of the first sensing electrodes 100 is noted as 100(i), where N≥i≥1. In a case where N≥2, the N first sensing electrodes 100 may be arranged at intervals along the first direction X. In the first sensing electrode 100, two adjacent first electrode blocks 110 are respectively denoted as a first electrode block 110_1 in an S-th row and a first electrode block 110_2 in a T-th row, where S is less than T by 1. Exemplarily, among the plurality of first electrode blocks 110, two adjacent first electrode blocks 110 (for example, the first electrode block 110_1 in the S-th row and the first electrode block 110_2 in the T-th row) are electrically connected through connection bridge(s) 400.

Exemplarily, a material of the first sensing electrode 100 is a transparent conductive material, for example, the transparent conductive material may be selected from at least one of indium tin oxide (ITO), aluminum doped zinc oxide (AZO), or the like, which is both electrically conductive and has a high light transmittance within a range the visible light.

The second sensing electrode 200 is arranged crosswise with the first sensing electrode 100. Exemplarily, the second sensing electrode 200 extends along the first direction X. If the touch layer TL needs to be provided therein with M second sensing electrodes 200, any one of the second sensing electrodes 200 is denoted as 200(j), where M≥j≥1. In a case where M≥2, the M second sensing electrodes 200 may be arranged at intervals along the second direction Y.

A second sensing electrode 200 includes a plurality of second electrode blocks 210 electrically connected to each other. In the second sensing electrode 200, two adjacent second electrode blocks 210 are respectively denoted as a second electrode block 210_1 in a W-th column and a second electrode block 210_2 in a V-th column, where W is less than V by 1. Exemplarily, the plurality of second electrode blocks 210 are arranged in a row to form a second sensing electrode 200. A (e.g., each) second sensing electrode 200 may have an integrated structure. For example, among the plurality of second electrode blocks 210, two adjacent second electrode blocks 210 (for example, the second electrode block 210_1 in the W-th column and the second electrode block 210_2 in the V-th column) are connected through a connection portion 220 to form an integrated structure. The second sensing electrode 200 and the first sensing electrode 100 are insulated from each other. Exemplarily, the second sensing electrode 200 passes between two adjacent first electrode blocks 110. The second sensing electrode 200 and the first electrode blocks 110 have an insulating gap therebetween, and the two are insulated from each other through the insulating gap.

Exemplarily, for a material of the second sensing electrode 200, reference may be made to the description of that of the first sensing electrode 100 above. For example, the second sensing electrode 200 and the first sensing electrode 100 may be made of the same or different materials.

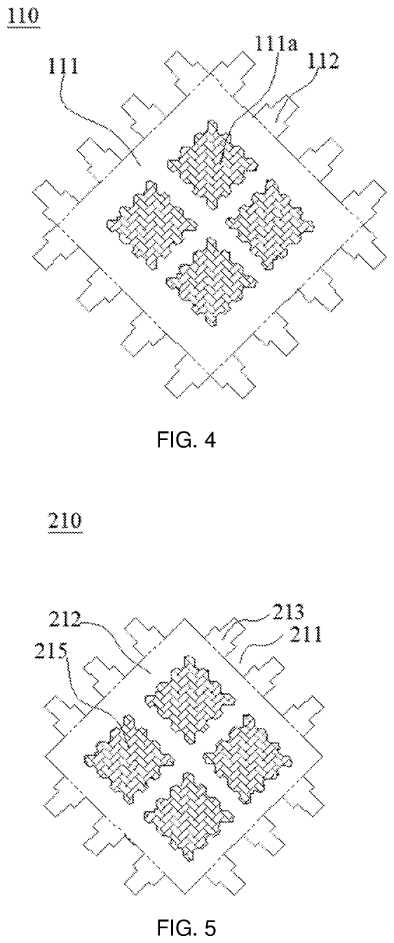

FIG. 4 is a structural diagram of a first electrode block in FIG. 2. FIG. 5 is a structural diagram of a second electrode block in FIG. 2. Referring to FIG. 2 to FIG. 5, in some embodiments, near an intersection position K of the first sensing electrode 100 and the second sensing electrode 200, the first electrode block 110 includes a first body 111 and a plurality of first finger portions 112 protruding from the first body 111. The second electrode block 210 have a plurality of notches 211 located at an edge thereof.

With continued reference to FIG. 2 to FIG. 5, exemplarily, sides, proximate to an intersection position K(ij) of the first sensing electrode 100 and the second sensing electrode 200(j), of two adjacent first electrode blocks 110 (for example, the first electrode block 110_1 in the S-th row and the first electrode block 110_2 in the T-th row) are each provided with a plurality of first finger portions 112. Exemplarily, a plurality of first finger portions 112 on each side are arranged at equal intervals along a side of the first body 111. In addition, near the intersection position K of the first sensing electrode 100 and the second sensing electrode 200, the second electrode block 210 has the plurality of notches 211 at the edge. Exemplarily, sides, proximate to the intersection position K(ij), of two adjacent second electrode blocks 210 (for example, the second electrode block 210_1 in the W-th column and the second electrode block 210_2 in the V-th column) are each provided with a plurality of notches 211. Exemplarily, the plurality of notches 211 are arranged at equal intervals along a side of the second sensing electrode 200. Exemplarily, the second electrode block 210 includes a second body 212 and second finger portions 213 protruding from the second body 212. A notch 211 is a gap between two adjacent second finger portions 213.

Referring to FIG. 3, the first finger portion 112 extends into the notch 211. Exemplarily, a first side ed1 and a second side ed2 of the first electrode block 110_1 in the S-th row are each provided with a plurality of first finger portions 112; and a third side ed3 and a fourth side ed4 of the first electrode block 110_2 in the T-th row are each provided with a plurality of first finger portions 112. Among them, the first side ed1 and the fourth side ed4 extend along a third direction E, and the second side ed2 and the third side ed3 extend along a fourth direction F. A fifth side ed5 and a sixth side ed6 of the second electrode block 210_1 in the W-th column are each provided with a plurality of notches 211; and a seventh side ed7 and an eighth side ed8 of the second electrode block 210_2 in the V-th column are each provided with a plurality of notches 211. Among them, the fifth side ed5 and the first side ed1 are opposite along the fourth direction F, the seventh side ed7 and the fourth side ed4 are opposite along the fourth direction F, the sixth side ed6 and the third side ed3 are opposite along the third direction E, and the eighth side ed8 and the second side ed2 are opposite along the third direction E. The plurality of first finger portions 112 on the first side ed1 and the plurality of notches 211 on the fifth side ed5 are arranged in one-to-one correspondence, and each first finger portion 112 on the first side ed1 extends into a notch 211 on the fifth side ed5. The plurality of first finger portions 112 on the second side ed2 and the plurality of notches 211 on the eighth side ed8 are arranged in one-to-one correspondence, and each first finger portion 112 on the second side ed2 extends into a notch 211 on the eighth side ed8. The plurality of first finger portions 112 on the third side ed3 and the plurality of notches 211 on the sixth side ed6 are arranged in one-to-one correspondence, and each first finger portion 112 on the third side ed3 extends into a notch 211 on the sixth side ed6. The plurality of first finger portions 112 on the fourth side ed4 and the plurality of notches 211 on the seventh side ed7 are arranged in one-to-one correspondence, and each first finger portion 112 on the fourth side ed4 extends into a notch 211 on the seventh side ed7.

Referring to FIG. 2 and FIG. 3, in a capacitor unit T of these embodiments, the first sensing electrode 100 is provided with the first finger portions 112, and the second sensing electrode 200 is provided with the notches 211, and the first finger portions 112 extend into the notches 211 of the second sensing electrode 200. In this way, the mutual capacitance Cm between the first sensing electrode 100 and the second finger portions 213 of the second sensing electrode 200 may be increased. Since the mutual capacitance Cm is positively related to the signal quantity ΔCm, the signal quantity ΔCm will also increase. However, the signal quantity ΔCm increases to a greater extent than the increase in mutual capacitance Cm. Therefore, in these embodiments, it is possible to recognize more accurately the signal change before and after a touch, and determine whether the touch occurs.

Referring to FIG. 4, some embodiments of the present disclosure provide a touch layer TL. A first body 111 of the touch layer TL is provided therein with a plurality of first dummy portions 111a. The first dummy portion 111a has a grid structure. Exemplarily, the first dummy portion 111a forms the grid structure through a plurality of conductive lines crossing each other. The plurality of first dummy portions 111a are evenly distributed in the first body 111. For example, the first dummy portions 111a are spaced apart at equal intervals in the first body 111 along its length and width directions. The first dummy portions 111a and the first electrode block 110 are electrically insulated from each other. The first dummy portion 111a and the first electrode block 110 have a gap therebetween, and the two are electrically insulated from each other through this gap. In this way, an area of the first body 111 may be reduced, thereby reducing a self-capacitance between the first body 111 and the cathode and charging time, and ultimately improving the scanning frequency and point reporting rate.

Exemplarily, a side length of the first dummy portion 111a is less than or equal to 1,000 micrometers to avoid a touch failure due to the user's finger touching only the first dummy portion 111a.

Referring to FIG. 5, in some other possible embodiments, a second electrode block 210 is provided therein with a plurality of second dummy portions 215. The second dummy portion 215 has a grid structure. Exemplarily, the second dummy portion 215 forms the grid structure through a plurality of conductive lines crossing each other. The plurality of second dummy portions 215 are evenly distributed in the second electrode block 210. For example, the second dummy portions 215 are spaced apart at equal intervals in the second electrode block 210 along its length and width directions. The second dummy portions 215 and the second electrode block 210 are electrically insulated from each other. The second dummy portion 215 and the second electrode block 210 have a gap therebetween, and the two are electrically insulated from each other through this gap. Effects achieved in these embodiments are the same as the effects achieved in the embodiments above, and will not be repeated here.

Exemplarily, a side length of the second dummy portion 215 is less than or equal to 1,000 micrometers. Effects achieved in these embodiments are the same as the effects achieved in the embodiments above, and will not be repeated here.

Referring to FIG. 4 and FIG. 5, in some possible embodiments, a first body 111 is provided therein with a plurality of first dummy portions 111a. The first dummy portion 111a has a grid structure. Exemplarily, the first dummy portion 111a forms the grid structure through a plurality of conductive lines crossing each other. The plurality of first dummy portions 111a are evenly distributed in the first body 111. For example, the first dummy portions 111a are spaced apart at equal intervals in the first body 111 along its length and width directions. The first dummy portions 111a and the first electrode block 110 are electrically insulated from each other. The first dummy portion 111a and the first electrode block 110 have a gap therebetween, and the two are electrically insulated from each other through this gap.

A second electrode block 210 is provided therein with a plurality of second dummy portions 215. The second dummy portion 215 has a grid structure. Exemplarily, the second dummy portion 215 forms the grid structure through a plurality of conductive lines crossing each other. The plurality of second dummy portions 215 are evenly distributed in the second electrode block 210. For example, the second dummy portions 215 are spaced apart at equal intervals in the second electrode block 210 along its length and width directions. The second dummy portions 215 and the second electrode block 210 are electrically insulated from each other. The second dummy portion 215 and the second electrode block 210 have a gap therebetween, and the two are electrically insulated from each other through this gap. Effects achieved in these embodiments are the same as the effects achieved in the embodiments above, and will not be repeated here.

Exemplarily, side lengths of the first dummy portion 111a and the second dummy portion 215 are each less than or equal to 1,000 micrometers. Effects achieved in these embodiments are the same as the effects achieved in the embodiments above, and will not be repeated here.

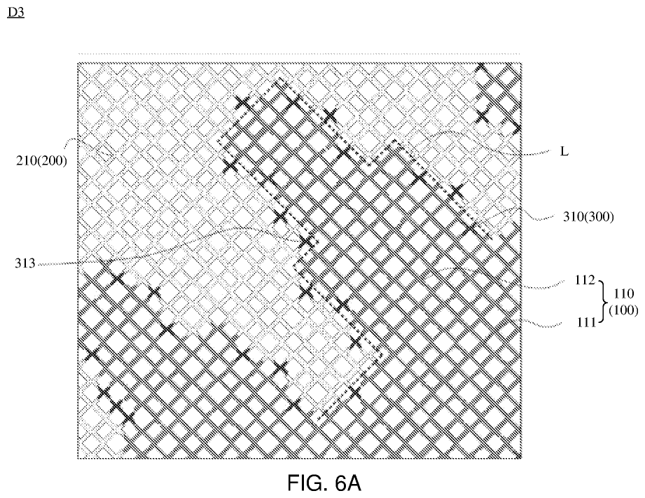

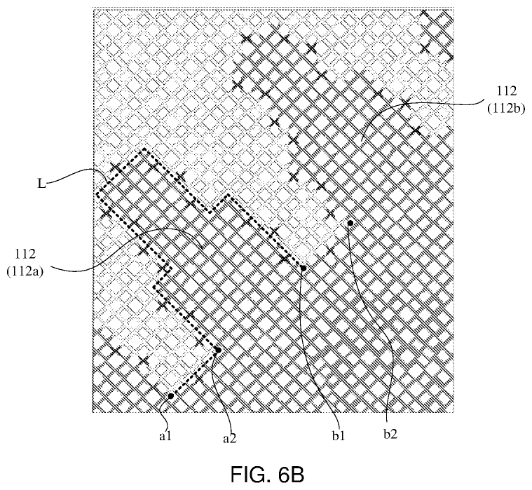

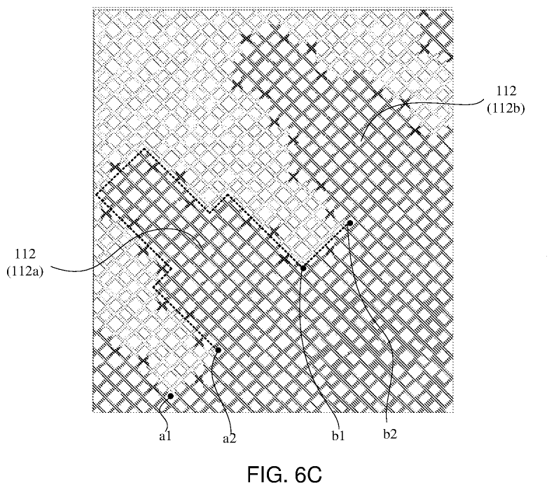

FIG. 6A is an enlarged view of the region D3 in FIG. 3. FIG. 6B is an alternative enlarged view of the region D3 in FIG. 3. FIG. 6C is another alternative enlarged view of the region D3 in FIG. 3. Referring to FIG. 6A to FIG. 6C, in some other embodiments, the touch layer TL further includes a conductive pattern group 300. The conductive pattern group 300 includes a plurality of conductive patterns 310 distributed spaced apart along a demarcation path segment L. The demarcation path segment L is a portion, between root endpoints of two adjacent first finger portions 112 at a same side, of a demarcation line between the first electrode block 110 and the second electrode block 210. The two adjacent first finger portions 112 are respectively denoted as a preceding first finger portion 112a and a subsequent first finger portion 112b. Root endpoints of the preceding first finger portion 112a are denoted as a preceding first root endpoint a1 and a preceding second root endpoint a2. Root endpoints of the subsequent first finger portion 112b are denoted as a subsequent first root endpoint b1 and a subsequent second root endpoint b2. For example, the demarcation path segment L is a portion, between root endpoints of the two adjacent first finger portions 112 at a first side, of the demarcation line between the first electrode block 110 and the second electrode block 210. In this way, of the demarcation path segment L, a starting point is the preceding first root endpoint a1 of the preceding first finger portion 112a, and an ending point is the subsequent first root endpoint b1 of the subsequent first finger portion 112b (referring to FIG. 6B). From the starting point to the ending point, the demarcation path segment L has a portion surrounding an edge of the first body 111 and a portion surrounding the preceding first finger portion 112a. As another example, the demarcation path segment L is a portion, between root endpoints of the two adjacent first finger portions 112 at a second side, of the demarcation line between the first electrode block 110 and the second electrode block 210. In this way, of the demarcation path segment L, a starting point is the preceding second root endpoint a2 of the preceding first finger portion 112a, and an ending point is the subsequent second root endpoint b2 of the subsequent first finger portion 112b (referring to FIG. 6C). From the starting point to the ending point, the demarcation path segment L has a portion surrounding the preceding first finger portion 112a and a portion surrounding an edge of the first body 111.

The conductive pattern 310 is jointly surrounded by the first electrode block 110 and the second electrode block 210. That is to say, two adjacent conductive patterns 310 are separated by the first electrode block 110 and the second electrode block 210. For example, two adjacent conductive patterns 310 are separated by the first body 111 of the first electrode block 110 and the second electrode block 210. As another example, two adjacent conductive patterns 310 are separated by the first finger portion 112 and the second electrode block 210. As another example, two adjacent conductive patterns 310 are separated by the first body 111, the first finger portion 112 and the second electrode block 210.

In addition, the conductive pattern 310 and both the first electrode block 110 and the second electrode block 210 are insulated from each other. Exemplarily, both the first electrode block 110 and the second electrode block 210 have a gap between the conductive pattern group 300. The conductive pattern 310 through the gap between the conductive pattern 310 and the first electrode block 110 to achieve insulation between the two. Similarly, the conductive pattern 310 through the gap between the conductive pattern 310 and the second electrode block 210 to achieve insulation between the two.

Exemplarily, for a material of the conductive pattern group 300, reference may be made to the description of that of the first sensing electrode 100 or the second sensing electrode 200 above. For example, the conductive pattern group 300 and the second sensing electrode 200 or the first sensing electrode 100 may be made of the same or different materials.

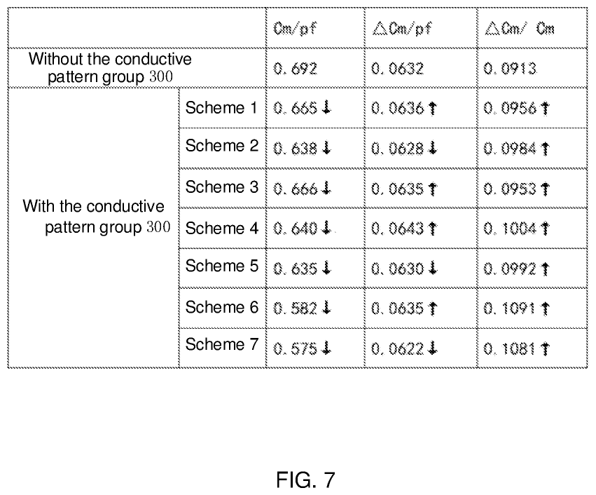

In these embodiments, the conductive pattern group 300 is provided between the first sensing electrode 100 and the second sensing electrode 200. The simulation data of the mutual capacitance Cm, the signal quantity ΔCm, and Cm/ΔCm are derived by simulating under the same electrode patterns, and the specific results are shown in FIG. 7 (FIG. 7 shows the simulation datasheets in some embodiments).

As can be seen, compared to a scheme without the conductive pattern group 300, in schemes with the conductive pattern group 300, the mutual capacitance Cm decreases with the addition of the conductive pattern group 300; the signal quantity ΔCm increases or decreases for different schemes; and the ΔCm/Cm increases. For different schemes, the signal quantity ΔCm increases or decreases, but for each scheme, ΔCm/Cm increases, this indicates that the degree of change (increase or decrease) of the signal quantity ΔCm is greater than the degree of change of the mutual capacitance Cm. Therefore, in these embodiments, it is possible to recognize more accurately the signal change before and after a touch.

With continued reference to FIG. 6A, some embodiments of the present disclosure provide a touch layer TL. The conductive pattern 310 of the touch layer TL is formed by a plurality of conductive lines crossing each other. The conductive pattern 310 has one intersection node 313. Exemplarily, the conductive pattern 310 is formed by two conductive lines crossing each other.

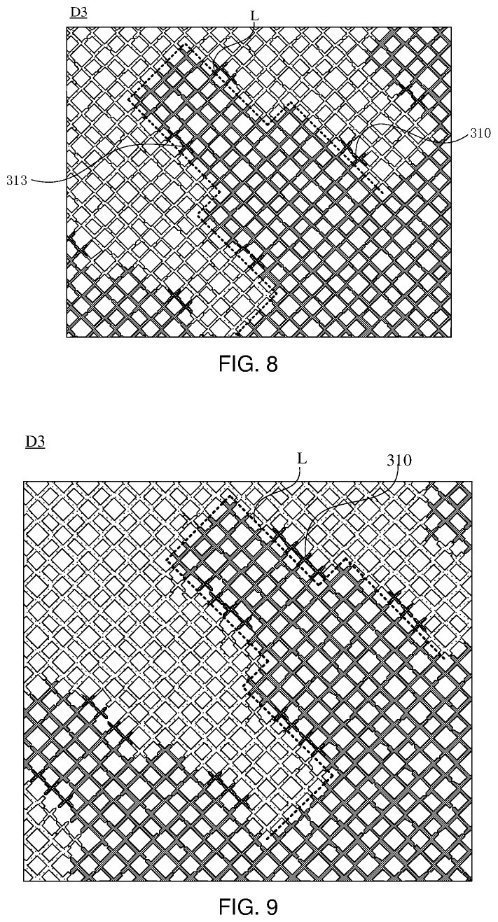

FIG. 8 is yet another alternative enlarged view of the region D3 in FIG. 3. FIG. 9 is yet another alternative enlarged view of the region D3 in FIG. 3. Referring to FIG. 8 and FIG. 9, in some possible embodiments, the conductive pattern 310 has at least two intersection nodes 313 distributed along the demarcation path segment L. Exemplarily, the conductive pattern 310 is formed by one conductive line arranged along the demarcation path segment L and at least two conductive lines crossing the demarcation path segment L, where the one conductive line crosses the at least two conductive lines. For example, the conductive pattern 310 shown in FIG. 8 is formed by one conductive line arranged along the demarcation path segment L and two conductive lines crossing the demarcation path segment L, where the one conductive line crosses the two conductive lines. As another example, the conductive pattern 310 shown in FIG. 9 is formed by one conductive line arranged along the demarcation path segment L and four conductive lines crossing the demarcation path segment L, where the one conductive line crosses the four conductive lines. In addition, these conductive patterns 310 each include at least two sub-conductive patterns, and these sub-conductive patterns may be separated from each other. For example, a sub-conductive pattern has an intersection node 313. Alternatively, these sub-conductive patterns may also be connected together. For example, a sub-conductive pattern has multiple intersection nodes 313.

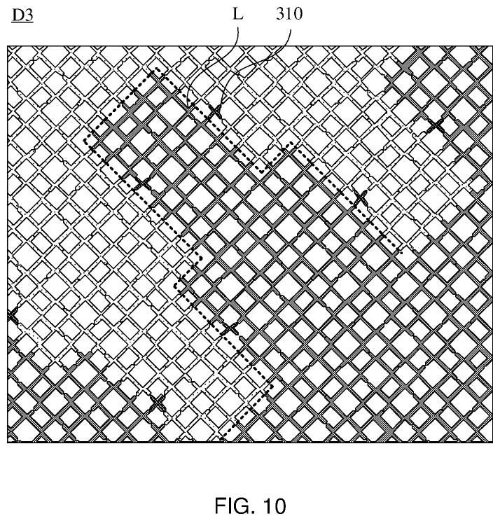

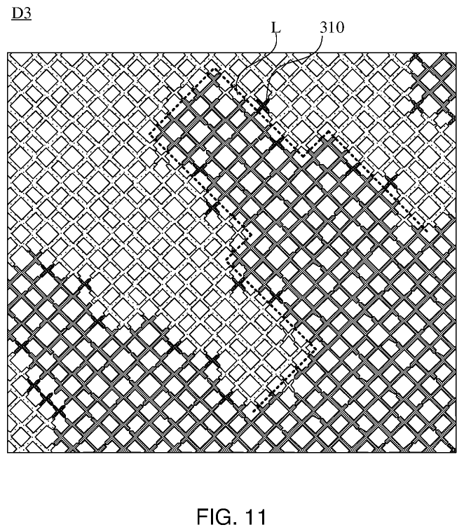

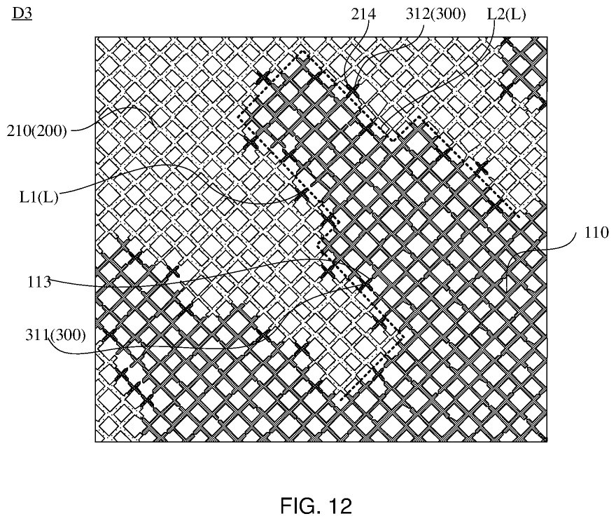

FIG. 10 is yet another alternative enlarged view of the region D3 in FIG. 3. FIG. 11 is yet another alternative enlarged view of the region D3 in FIG. 3. FIG. 12 is yet another alternative enlarged view of the region D3 in FIG. 3. With continued reference to FIG. 10 to FIG. 12, some embodiments of the present disclosure provide a touch layer TL. In the conductive pattern group 300 of the touch layer TL, a total length of the conductive patterns is less than or equal to half of a length of the demarcation path segment L. Referring to FIG. 7, a conductive pattern group 300 of Scheme 1 (referring to FIG. 10) has 4 conductive patterns 310; a conductive pattern group 300 of Scheme 4 (referring to FIG. 11) has 8 conductive patterns 310; a conductive pattern group 300 of Scheme 6 (referring to FIG. 12) has 15 conductive patterns 310. According to the simulation data shown in FIG. 7, if allowed, as the number of conductive patterns 310 increases, the effect of recognizing the signal change before and after touch becomes better.

With continued reference to FIG. 12, in some possible embodiments, the conductive pattern group 300 includes at least one (e.g., one or more) first conductive pattern 311. The first conductive pattern 311 is a conductive pattern.

The first electrode block 110 has a grid structure. Exemplarily, the first electrode block 110 forms the grid structure through a plurality of conductive lines crossing each other. The first electrode block 110 is provided with at least one first grid point vacancy 113 along the demarcation path segment L. The first grid point vacancy 113 causes the grid structure of the first electrode block 110 to form a recessed gap at an edge thereof. The first conductive pattern 311 is disposed in the first grid point vacancy 113. Exemplarily, the first grid point vacancy 113 and the first conductive pattern 311 are same in number and are arranged in one-to-one correspondence. In these embodiments, the first conductive pattern 311 is arranged in the first grid point vacancy 113, which may reduce the mutual capacitance value Cm and increase the capacitance difference ΔCm, and then ΔCm/Cm also increases, so that it is possible to more accurately recognize whether there is a touch or not.

With continued reference to FIG. 12, in still some possible embodiments, the conductive pattern group 300 includes at least one (e.g., one or more) second conductive pattern 312. The second conductive pattern 312 is a conductive pattern.

The second electrode block 210 has a grid structure. Exemplarily, the second electrode block 210 forms the grid structure through a plurality of conductive lines crossing each other. The second electrode block 210 is provided with at least one second grid point vacancy 214 along the demarcation path segment L. Exemplarily, the second grid point vacancy 214 causes the grid structure of the second electrode block 210 to form a recessed gap at an edge thereof. The second conductive pattern 312 is disposed in the second grid point vacancy 214. Exemplarily, the second grid point vacancy 214 and the second conductive pattern 312 are same in number and are arranged in one-to-one correspondence. In these embodiments, the second conductive pattern 312 is arranged in the second grid point vacancy 214, which may reduce the mutual capacitance value Cm and increase the capacitance difference ΔCm, and then ΔCm/Cm also increases, so that it is possible to more accurately recognize whether there is a touch or not.

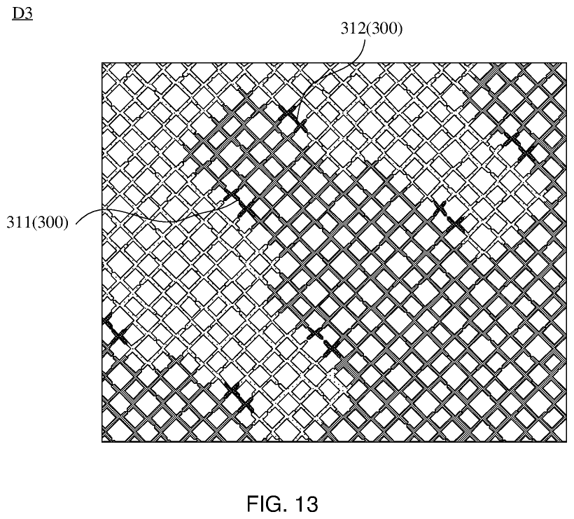

FIG. 13 is yet another alternative enlarged view of the region D3 in FIG. 3. Referring to FIG. 13, exemplarily, in the conductive pattern group 300, the first conductive pattern 311 and the second conductive pattern 312 are same in number. In this way, before and after the conductive pattern group 300 is added, the change amount of the area of the first sensing electrode 100 (not shown in the figure) is equal to the change amount of the area of the second sensing electrode 200 (not shown in the figure), thereby reducing the mutual capacitance value Cm while ensuring that the capacitance difference ΔCm is substantially unchanged, and then ΔCm/Cm also increases, so that it is possible to more accurately recognize whether there is a touch or not.

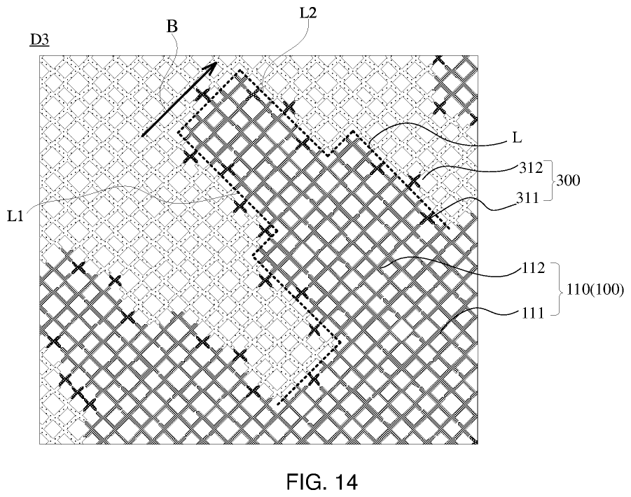

FIG. 14 is yet another alternative enlarged view of the region D3 in FIG. 3. Referring to FIG. 14, in some possible embodiments, the demarcation path segment L includes a first section L1 and a second section L2 that surround the first finger portion 112 and are opposite along a width direction B of the first finger portion 112. For example, the first section L1 is a portion of the demarcation path segment L connected to a portion surrounding the first body 111, and the second section L2 is a portion of the demarcation path segment L away from the portion surrounding the first body 111. As another example, the second section L2 is a portion of the demarcation path segment L connected to a portion surrounding the first body 111, and the first section L1 is a portion of the demarcation path segment L away from the portion surrounding the first body 111.

The conductive pattern group 300 includes M1 first conductive patterns 311 distributed along the first section L1, and M2 second conductive patterns 312 distributed along the second section L2. For example, the M1 first conductive patterns 311 are distributed at equal intervals along the first section L1; and the M2 second conductive patterns 312 are distributed at equal intervals along the second section L2. Here, M1 and M2 are both greater than or equal to 1.

Exemplarily, M1 and M2 are equal. In this way, before and after the conductive pattern group 300 is added, the change amount of the area of the first sensing electrode 100 (not shown in the figure) is equal to the change amount of the area of the second sensing electrode 200 (not shown in the figure), so that the capacitance value of the second sensing electrode 200 with the cathode, and the capacitance value of the first sensing electrode 100 with the cathode are kept consistent, which facilitates the debugging of the TIC.

Specifically, at least one (e.g., one or more) of the M1 first conductive patterns 311 and at least one (e.g., one or more) of the M2 second conductive patterns 312 are arranged opposite along the width direction B of the first finger portion 112. For example, the M1 first conductive patterns 311 and the M2 second conductive patterns 312 are arranged in one-to-one correspondence along the width direction B of the first finger portion 112.

With continued reference to FIG. 14, in some other possible embodiments, the conductive pattern group 300 includes M3 second conductive patterns 312 distributed along the first section L1, and M4 first conductive patterns 311 distributed along the second section L2. For example, the M3 second conductive patterns 312 are distributed at equal intervals along the first section L1; and the M4 first conductive patterns 311 are distributed at equal intervals along the second section L2. Here, M3 and M4 are both greater than or equal to 1.

Exemplarily, M3 and M4 are equal. Effects achieved in these embodiments are the same as the effects achieved in the embodiments above, and will not be repeated here.

Specifically, at least one (e.g., one or more) of the M3 second conductive patterns 312 and at least one (e.g., one or more) of the M4 first conductive patterns 311 are arranged opposite along the width direction B of the first finger portion 112. For example, the M3 second conductive patterns 312 and the M4 first conductive patterns 311 are arranged in one-to-one correspondence along the width direction B of the first finger portion 112.

With continued reference to FIG. 14, in yet some other possible embodiments, the conductive pattern group 300 further includes M1 first conductive patterns 311 and M3 second conductive patterns 312 which are distributed along the first section L1. For example, the M1 first conductive patterns 311 and the M3 second conductive patterns 312 are alternately distributed along the first section L1. As another example, the M1 first conductive patterns 311 and the M3 second conductive patterns 312 are sequentially distributed along the first section L1. And, the conductive pattern group 300 further includes M3 second conductive patterns 312 and M4 first conductive patterns 311 which are distributed along the second section L2. For example, the M3 second conductive patterns 312 and the M4 first conductive patterns 311 are alternately distributed along the second section L2. As another example, the M3 second conductive patterns 312 and the M4 first conductive patterns 311 are sequentially distributed along the second section L2. Here, M1, M2, M3 and M4 are each greater than or equal to 1.

Exemplarily, M1 and M2 are equal, and M3 and M4 are equal. Effects achieved in these embodiments are the same as the effects achieved in the embodiments above, and will not be repeated here.

Specifically, at least one (e.g., one or more) of the M1 first conductive patterns 311 and at least one (e.g., one or more) of the M2 second conductive patterns 312 are arranged opposite along the width direction B of the first finger portion 112. For example, the M1 first conductive patterns 311 and the M2 second conductive patterns 312 are arranged in one-to-one correspondence along the width direction B of the first finger portion 112. At least one (e.g., one or more) of the M3 second conductive patterns 312 and at least one (e.g., one or more) of the M4 first conductive patterns 311 are arranged opposite along the width direction B of the first finger portion 112. For example, the M3 second conductive patterns 312 and the M4 first conductive patterns 311 are arranged in one-to-one correspondence along the width direction B of the first finger portion 112.

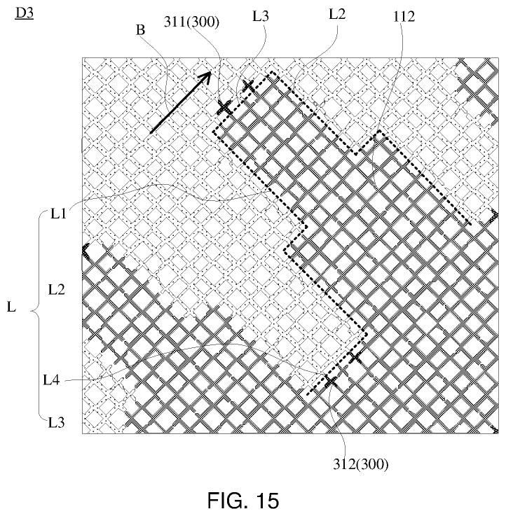

FIG. 15 is yet another alternative enlarged view of the region D3 in FIG. 3. Referring to FIG. 15, in some possible embodiments, the demarcation path segment L includes a third section L3 surrounding the first finger portion 112 and extending substantially along the width direction B of the first finger portion 112. Exemplarily, the third section L3 is a portion located between the first section L1 and the second section L2 of the demarcation path segment L. And, the demarcation path segment L includes a fourth section L4 located between two adjacent first finger portions 112. For example, the fourth section L4 is a portion of the demarcation path segment L connected to the starting point of the first section L1.

The conductive pattern group 300 further includes N1 first conductive patterns 311 distributed along the third section L3, and N2 second conductive patterns 312 distributed along the fourth section L4. For example, the N1 first conductive patterns 311 are distributed at equal intervals along the third section L3; and the N2 second conductive patterns 312 are distributed at equal intervals along the fourth section L4. Here, N1 and N2 are both greater than or equal to 1.

Exemplarily, N1 and N2 are equal. Effects achieved in these embodiments are the same as the effects achieved in the embodiments above, and will not be repeated here.

In some other possible embodiments, the conductive pattern group 300 further includes Q1 second conductive patterns 312 distributed along the third section L3, and O2 first conductive patterns 311 distributed along the fourth section L4. For example, the Q1 second conductive patterns 312 are distributed at equal intervals along the third section L3; and the Q2 first conductive patterns 311 are distributed at equal intervals along the fourth section L4. Here, Q1 and Q2 are both greater than or equal to 1.

Exemplarily, Q1 and Q2 are equal. Effects achieved in these embodiments are the same as the effects achieved in the embodiments above, and will not be repeated here.

With continued reference to FIG. 15, in yet some other possible embodiments, the conductive pattern group 300 further includes N1 first conductive patterns 311 and Q1 second conductive patterns 312 which are distributed along the third section L3. For example, the N1 first conductive patterns 311 and the Q1 second conductive patterns 312 are alternately distributed along the third section L3. As another example, the N1 first conductive patterns 311 and the Q1 second conductive patterns 312 are sequentially distributed along the third section L3. And, the conductive pattern group 300 further includes N2 second conductive patterns 312 and Q2 first conductive patterns 311 which are distributed along the fourth section L4. For example, the N2 second conductive patterns 312 and the Q2 first conductive patterns 311 are alternately distributed along the fourth section L4. As another example, the N2 second conductive patterns 312 and the Q2 first conductive patterns 311 are sequentially distributed along the fourth section L4.

Here, N1, N2, Q1 and Q2 are each greater than or equal to 1. Effects achieved in these embodiments are the same as the effects achieved in the embodiments above, and will not be repeated here.

FIG. 16 is yet another alternative enlarged view of the region D3 in FIG. 3. Referring to FIG. 16, some embodiments of the present disclosure provide a touch layer TL. In a case where the conductive pattern group 300 of the touch layer TL includes the N1 first conductive patterns 311 and the N2 second conductive patterns 312, at least one (e.g., one or more) of the N1 first conductive patterns 311 is distributed at an end of the third section L3. For example, a first conductive pattern 311 is distributed at each of the starting point and the ending point of the third section L3. As another example, a first conductive pattern 311 is distributed at the starting point of the third section L3, but no first conductive pattern 311 is distributed at the ending point. As another example, a first conductive pattern 311 is distributed at the ending point of the third section L3, but no first conductive pattern 311 is distributed at the starting point.

At least one (e.g., one or more) of the N2 second conductive patterns 312 is distributed at an end of the fourth section L4. For example, a second conductive pattern 312 is distributed at each of the starting point and the ending point of the fourth section L4. As another example, a second conductive pattern 312 is distributed at the starting point of the fourth section L4, but no second conductive pattern 312 is distributed at the ending point. As another example, a second conductive pattern 312 is distributed at the ending point of the fourth section L4, but no second conductive pattern 312 is distributed at the starting point. Effects achieved in these embodiments are the same as the effects achieved in the embodiments above, and will not be repeated here.

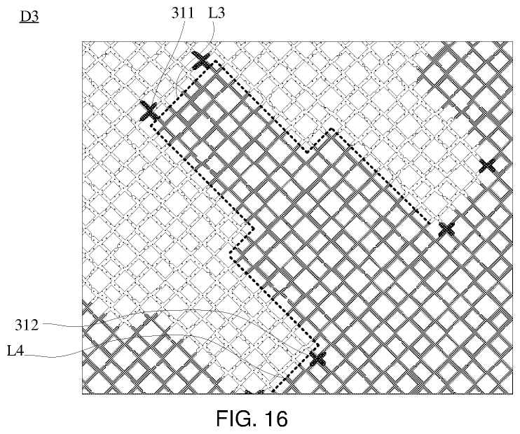

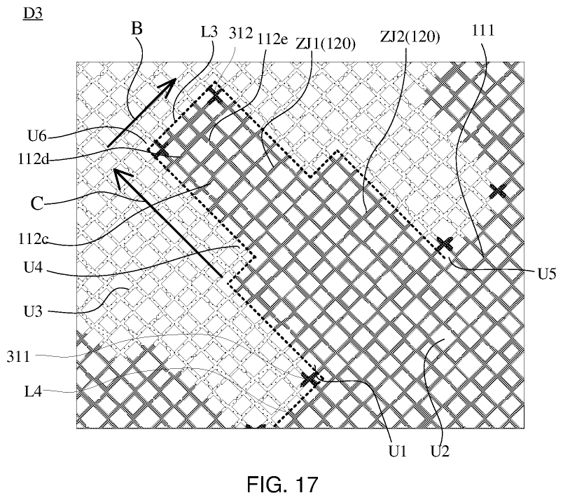

FIG. 17 is yet another alternative enlarged view of the region D3 in FIG. 3. Referring to FIG. 17, some embodiments of the present disclosure provide a touch layer TL. The conductive pattern group 300 of the touch layer TL includes the Q1 second conductive patterns and the Q2 first conductive patterns.

At least one (e.g., one or more) of the Q1 second conductive patterns 312 is distributed at an end of the third section L3. For example, a second conductive pattern 312 is distributed at each of the starting point and the ending point of the third section L3.

As another example, a second conductive pattern 312 is distributed at the starting point of the third section L3, but no second conductive pattern 312 is distributed at the ending point. As another example, a second conductive pattern 312 is distributed at the ending point of the third section L3, but no second conductive pattern 312 is distributed at the starting point. Effects achieved in these embodiments are the same as the effects achieved in the embodiments above, and will not be repeated here.

At least one (e.g., one or more) of the Q2 first conductive patterns 311 is distributed at an end of the fourth section L4. For example, a first conductive pattern 311 is distributed at each of the starting point and the ending point of the fourth section L4. As another example, a first conductive pattern 311 is distributed at the starting point of the fourth section L4, but no first conductive pattern 311 is distributed at the ending point. As another example, a first conductive pattern 311 is distributed at the ending point of the fourth section L4, but no first conductive pattern 311 is distributed at the starting point. Effects achieved in these embodiments are the same as the effects achieved in the embodiments above, and will not be repeated here.

Referring to FIG. 17, some embodiments of the present disclosure provide a touch layer TL. The first finger portion 112 of the touch layer TL includes a first finger segment ZJ1 and a second finger segment ZJ2. The first finger segment ZJ1 is further away from the first body 111 than the second finger segment ZJ2. The width of the first finger segment ZJ1 is a dimension of the first finger segment ZJ1 along the width direction B of the first finger portion 112. The width of the second finger segment ZJ2 is a dimension of the second finger segment ZJ2 along the width direction B of the first finger portion 112. The width of the first finger segment ZJ1 is less than the width of the second finger segment ZJ2. In this way, the first finger portion 112 includes two patterns with unequal areas. Therefore, the human eye will recognize the first finger portion 112 as two patterns, thus reducing the visibility of the first finger portion 112.

In some possible implementations, a portion of the demarcation path segment L surrounding the first finger segment ZJ1 is provided with at least one (e.g., one or more) conductive pattern 310.

In some other possible implementations, a portion of the demarcation path segment L surrounding the second finger segment ZJ2 is provided with at least one (e.g., one or more) conductive pattern 310.

In yet some other possible implementations, a portion of the demarcation path segment L surrounding the first finger segment ZJ1 is provided with at least one (e.g., one or more) conductive pattern 310, and a portion of the demarcation path segment L surrounding the second finger segment ZJ2 is provided with at least one (e.g., one or more) conductive pattern 310.

Referring to FIG. 17, some embodiments of the present disclosure provide a touch layer TL. The first finger portion 112 of the touch layer TL has a grid structure. Exemplarily, the first finger portion 112 forms the grid structure through a plurality of conductive lines crossing each other.

In some possible embodiments, along the width direction B of the first finger portion 112, areas of two adjacent squares 112c are not equal. Since the conductive lines forming the grid structure of the first finger portions 112 are metal, they will block light. Therefore, the conductive lines are arranged around RGB pixels during layout. The sizes of the RGB pixels are different, so in these embodiments, the RGB pixels of different sizes may be bypassed to reduce visibility.

In some other possible embodiments, along an extension direction C of the first finger portion 112, areas of two adjacent squares 112c are not equal. Here, the extension direction C and the width direction B intersect each other. Effects achieved in these embodiments are the same as the effects achieved in the embodiments above, and will not be repeated here.

In yet some other possible embodiments, along the width direction B of the first finger portion 112, areas of two adjacent squares 112c are not equal; and along an extension direction C of the first finger portion 112, areas of two adjacent squares 112c are not equal. Here, the extension direction C and the width direction B intersect each other. Effects achieved in these embodiments are the same as the effects achieved in the embodiments above, and will not be repeated here.

Referring to FIG. 17, some embodiments of the present disclosure provide a touch layer TL. The first finger portion 112 of the touch layer TL has a grid structure. Exemplarily, the first finger portion 112 forms the grid structure through a plurality of conductive lines crossing each other.

In some possible embodiments, the first finger portion 112 has a first break 112d, and the first break 112d communicates two adjacent squares 112c of the first finger portion 112 in the width direction B. In this way, the first finger portion 112 may be divided into multiple patterns, thereby reducing the visibility of the first finger portion 112.

In some other possible embodiments, the first finger portion 112 has a second break 112e, and the second break 112e communicates two adjacent squares 112c of the first finger portion 112 in the extension direction C. Effects achieved in these embodiments are the same as the effects achieved in the embodiments above, and will not be repeated here.

In yet some other possible embodiments, the first finger portion 112 has a first break 112d, and the first break 112d communicates two adjacent squares 112c of the first finger portion 112 in the width direction B. The first finger portion 112 further has a second break 112e, and the second break 112e communicates two adjacent squares 112c of the first finger portion 112 in the extension direction C. Effects achieved in these embodiments are the same as the effects achieved in the embodiments above, and will not be repeated here.

In yet some other possible embodiments, the first body 111 has a grid structure. The first body 111 has a third break, and the third break communicates two adjacent squares of the first body 111 in the third direction E. Effects achieved in these embodiments are the same as the effects achieved in the embodiments above, and will not be repeated here.

In yet some other possible embodiments, the first body 111 has a grid structure. The first body 111 has a fourth break, and the fourth break communicates two adjacent squares of the first body 111 in the fourth direction F. Effects achieved in these embodiments are the same as the effects achieved in the embodiments above, and will not be repeated here.

In yet some other possible embodiments, the second electrode 210 has a grid structure. The second electrode 210 has a fifth break, and the fifth break communicates two adjacent squares of the second electrode 210 in the third direction E. Effects achieved in these embodiments are the same as the effects achieved in the embodiments above, and will not be repeated here.

In yet some other possible embodiments, the second electrode 210 has a grid structure. The second electrode 210 has a sixth break, and the sixth break communicates two adjacent squares of the second electrode 210 in the fourth direction F. Effects achieved in these embodiments are the same as the effects achieved in the embodiments above, and will not be repeated here.

Referring to FIG. 17 and FIG. 1C, some embodiments of the present disclosure provide a touch layer TL. The first electrode blocks 110, the second electrode blocks 210 and the conductive patterns 310 of the touch layer TL form a grid structure. The grid structure includes a plurality of squares, and these squares include at least one (e.g., one or more) first square U1. The first square U1 is surrounded by a first electrode block 110, a second electrode block 210 and a conductive pattern 310.

In addition, the above-mentioned display panel DP further includes a plurality of sub-pixels, and the sub-pixel is a portion of the light-emitting layer DP123b located in an opening P of the above-mentioned pixel define layer DP121. The first square U1 is directly opposite to an opening P along a thickness direction of the touch layer TL. That is to say, the first square U1 and the opening P have an overlapping area in the thickness direction of the touch layer TL.

With continued reference to FIG. 17 and FIG. 1C, in some possible implementations, the plurality of squares further include a second square U2. The second square U2 is surrounded by a first electrode block 110. The second square U2 is directly opposite to an opening P along the thickness direction of the touch layer TL. That is to say, the second square U2 and the opening P have an overlapping area in the thickness direction of the touch layer TL.

With continued reference to FIG. 17 and FIG. 1C, in some possible implementations, the plurality of squares further include a third square U3. The third square U3 is surrounded by a second electrode block 210. The third square U3 is directly opposite to an opening P along the thickness direction of the touch layer TL. That is to say, the third square U3 and the opening P have an overlapping area in the thickness direction of the touch layer TL.

With continued reference to FIG. 17 and FIG. 1C, in some possible implementations, the plurality of squares further include a fourth square U4. The fourth square U4 is jointly surrounded by a first electrode block 110 and a second electrode block 210. The fourth square U4 is directly opposite to an opening P along the thickness direction of the touch layer TL. That is to say, the fourth square U4 and the opening P have an overlapping area in the thickness direction of the touch layer TL.

With continued reference to FIG. 17 and FIG. 1C, in some possible implementations, the plurality of squares further include a fifth square U5. The fifth square U5 is jointly surrounded by a first electrode block 110 and a conductive pattern 310. The fifth square U5 is directly opposite to an opening P along the thickness direction of the touch layer TL. That is to say, the fifth square U5 and the opening P have an overlapping area in the thickness direction of the touch layer TL.

With continued reference to FIG. 17 and FIG. 1C, in some possible implementations, the plurality of squares further include a sixth square U6. The sixth square U6 is jointly surrounded by a second electrode block 210 and a conductive pattern 310. The sixth square U6 is directly opposite to an opening P along the thickness direction of the touch layer TL. That is to say, the sixth square U6 and the opening P have an overlapping area in the thickness direction of the touch layer TL.

Some embodiments of the present disclosure provide a method for manufacturing a touch layer TL. The manufacturing method includes: forming a first sensing electrode, a second sensing electrode and a conductive pattern group. The first sensing electrode and the second sensing electrode are arranged crosswise and insulated from each other. The first sensing electrode includes a plurality of first electrode blocks electrically connected to each other; and the second sensing electrode includes a plurality of second electrode blocks electrically connected to each other. A first electrode block includes a first body and a plurality of first finger portions protruding from the first body. A second electrode block includes a plurality of notches located at an edge thereof. A first finger portion extends into a notch. The conductive pattern group includes a plurality of conductive patterns distributed spaced apart along a demarcation path segment, and the demarcation path segment is a portion, between root endpoints of two adjacent first finger portions at a same side, of a demarcation line between the first electrode block and the second electrode block. A conductive pattern is jointly surrounded by the first electrode block and the second electrode block, and is insulated from both the first electrode block and the second electrode block.

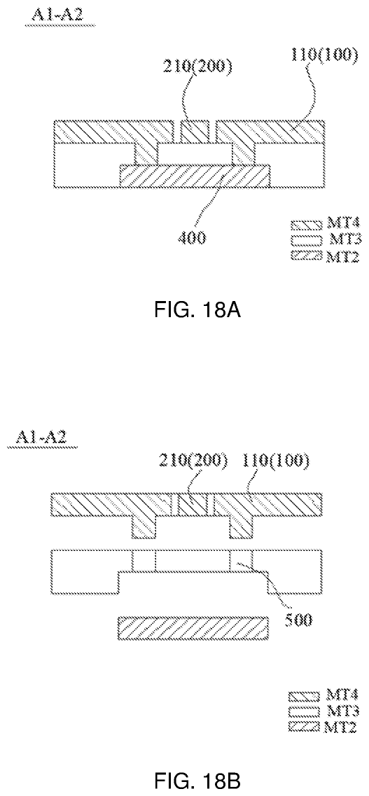

FIG. 18A is a sectional view taken along the line A1-A2 in FIG. 3. FIG. 18B is an exploded view of FIG. 18A. Referring to FIG. 18A and FIG. 18B, some embodiments of the present disclosure provide a method for manufacturing a touch layer TL. The manufacturing method includes forming a fifth conductive pattern layer MT2, an insulating layer MT3 and a sixth conductive pattern layer MT4. The fifth conductive pattern layer MT2 includes a plurality of connection bridges 400. The sixth conductive pattern layer MT4 includes the above first sensing electrode 100, the second sensing electrode 200 and the conductive pattern group 300 (not shown in the figure).

With continued reference to FIG. 18A and FIG. 18B, the fifth conductive pattern layer MT2 and the sixth conductive pattern layer MT4 are stacked, that is, they are arranged in the thickness direction of the touch layer TL. For example, the fifth conductive pattern layer MT2 may be stacked below the sixth conductive pattern layer MT4. Specifically, the fifth conductive pattern layer MT2 is formed earlier than the sixth conductive pattern layer MT4. As another example, the fifth conductive pattern layer MT2 may be stacked above the sixth conductive pattern layer MT4. Specifically, in the method for manufacturing the touch layer, the sixth conductive pattern layer MT4 is formed before the fifth conductive pattern layer MT2 is formed.

With continued reference to FIG. 18A and FIG. 18B, the insulating layer MT3 is provided with openings 500, and a connection bridge 400 is electrically connected to a first electrode block 110 through openings 500. The insulating layer MT3 extends between the sixth conductive pattern layer MT4 and the fifth conductive pattern layer MT2. For example, orthographic projections, on the insulating layer MT3, of each first electrode block 110, each second electrode block 210 and each conductive pattern group 300 in the sixth conductive pattern layer MT4 are within an outline (i.e., a border) of the insulating layer MT3; and an orthographic projection, on the insulating layer MT3, of the connection bridge 400 in the fifth conductive pattern layer MT2 is within the outline of the insulating layer MT3. As another example, if all openings 500 in the insulating layer MT3 are ignored, an orthographic projection of the insulating layer MT3 on the display panel DP (shown in FIG. 1B) covers the display area AA (shown in FIG. 1B).

Exemplarily, a material of the insulating layer MT3 may be an inorganic insulating material such as silicon oxide, aluminum oxide, or a silicon nitride compound (SiNx); and of course, the material of the insulating layer MT3 may also be an organic insulating material.

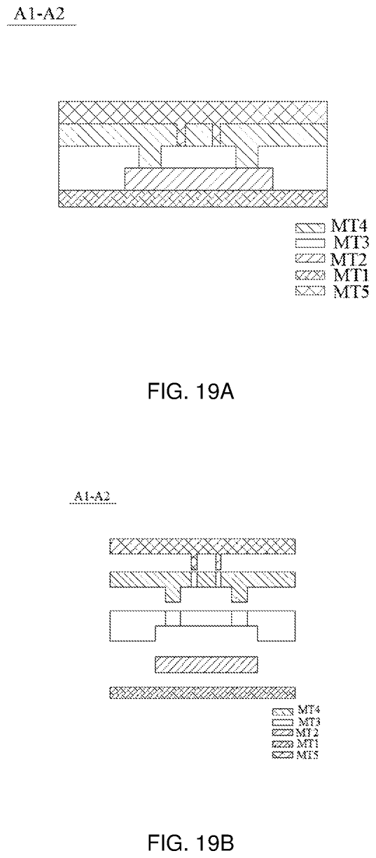

FIG. 19A is another sectional view taken along the line A1-A2 in FIG. 3. FIG. 19B is an exploded view of FIG. 19A. Referring to FIG. 19A and FIG. 19B, the touch layer TL may further include a base MT1, and the base MT1 is stacked below the fifth conductive pattern layer MT2 (i.e., on a side of the fifth conductive pattern layer MT2 away from the sixth conductive pattern layer MT4). The base MT1 may be a rigid base or a flexible base. The rigid base may include, for example, at least one of a glass base, a polymethyl methacrylate (PMMA) base, a quartz base and a metal base. The flexible base may include, for example, at least one of a polyethylene terephthalate (PET) base, a polyethylene naphthalate (PEN) base and a polyimide (PI) base.

With continued reference to FIG. 19A and FIG. 19B, the touch layer TL may further include a protective layer 500, and the protective layer 500 is stacked above the sixth conductive pattern layer MT4 (i.e., on a side of the sixth conductive pattern layer MT4 away from the fifth conductive pattern layer MT2). For a material of the protective layer 500, reference may be made to the description of that of the insulating layer MT3 above. For example, the protective layer 500 and the insulating layer MT3 may be made of same or different materials.

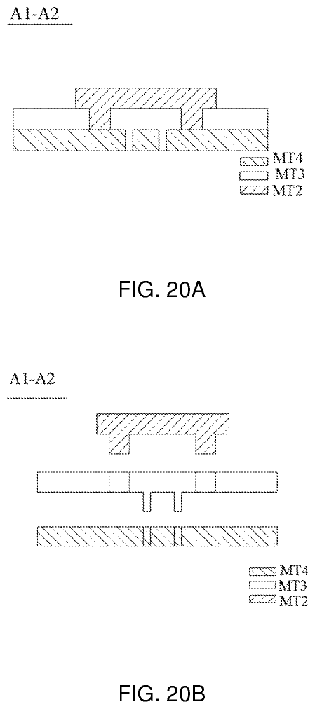

FIG. 20A is yet another sectional view taken along the line A1-A2 in FIG. 3. FIG. 20B is an exploded view of FIG. 20A. Referring to FIG. 20A and FIG. 20B, some embodiments of the present disclosure provide a method for manufacturing a touch layer TL. The manufacturing method includes: forming a sixth conductive pattern layer MT4, an insulating layer MT3 and a fifth conductive pattern layer MT2 sequentially from bottom to top. For example, the fifth conductive pattern layer MT2, the insulating layer MT3 and the sixth conductive pattern layer MT4 may be formed sequentially. For other structures, reference may be made to the description in the embodiments above. Effects achieved in these embodiments are the same as the effects achieved in the embodiments above, and will not be repeated here.

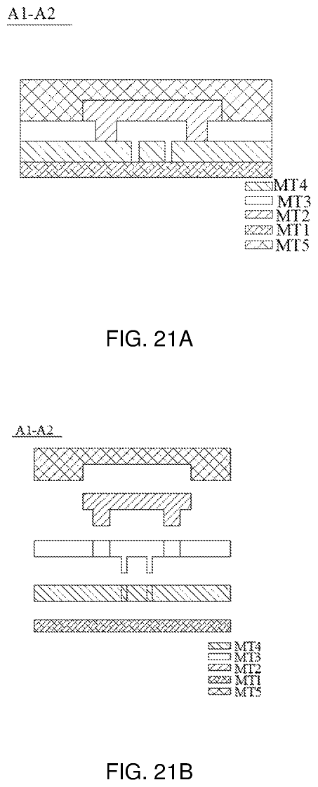

FIG. 21A is yet another sectional view taken along line A1-A2 in FIG. 3. FIG. 21B is an exploded view of FIG. 21A. Referring to FIG. 21A and FIG. 21B, some embodiments of the present disclosure provide a method for manufacturing a touch layer TL. Based on the touch layer TL shown in FIG. 20A, this manufacturing method may further include: forming a protective layer MT5, or forming a base MT1, or forming a protective layer MT5 and a base MT1. For example, in the method for manufacturing the touch layer TL, the sixth conductive pattern layer MT4, the insulating layer MT3, the fifth conductive pattern layer MT2, and the protective layer MT5 may be formed on the base MT1 in a sequential order. For other structures, reference may be made to the description in the embodiments above. Effects achieved in these embodiments are the same as the effects achieved in the embodiments above, and will not be repeated here.

For a material of the protective layer MT5, reference may be made to the description of that of the insulating layer MT3 above. For example, the protective layer MT5 and the insulating layer MT3 may be made of same or different materials.

In the embodiments of the present disclosure, the “pattern layer” may be a layer structure including specific patterns, which is formed by a patterning process on at least one film layer formed by the same film forming process. Depending on different specific patterns, the patterning process may include several coating, exposure, development or etching processes, and the specific patterns in the formed layer structure may be continuous or discontinuous, and these specific patterns may also be at different heights (or have different thicknesses).

A conductive pattern layer above is a pattern layer having conductive properties. The materials of the individual patterns in this pattern layer (e.g., the first sensing electrode 100, the second sensing electrode 200, and the conductive pattern group 300) may be the same.

Exemplarily, a material of the conductive pattern layer is a metal conductive material, such as titanium, aluminum and titanium (Ti—Al—Ti).

The foregoing descriptions are merely specific implementations of the present disclosure, but the protection scope of the present disclosure is not limited thereto. Any changes or replacements that a person skilled in the art could readily conceive of within the technical scope of the present disclosure shall be included in the protection scope of the present disclosure. Therefore, the protection scope of the present disclosure shall be subject to the protection scope of the claims.

1. A touch layer, comprising:
a first sensing electrode, including a plurality of first electrode blocks electrically connected to each other; and
a second sensing electrode, arranged crosswise with the first sensing electrode and insulated from each other, including a plurality of second electrode blocks electrically connected to each other;
wherein a first electrode block includes a first body and a plurality of first finger portions protruding from the first body, a second electrode block has a plurality of notches located at an edge thereof, and a first finger portion extends into a notch;
the touch layer further comprises:
a conductive pattern group, including a plurality of conductive patterns distributed spaced apart along a demarcation path segment, the demarcation path segment being a portion, between root endpoints of two adjacent first finger portions at a same side, of a demarcation line between the first electrode block and the second electrode block, wherein a conductive pattern is jointly surrounded by the first electrode block and the second electrode block, and is insulated from both the first electrode block and the second electrode block.

2. The touch layer according to claim 1, wherein
the conductive pattern is formed by a plurality of conductive lines crossing each other; and the conductive pattern has one intersection node, or at least two intersection nodes distributed along the demarcation path segment.

3. The touch layer according to claim 1, wherein
in the conductive pattern group, a total length of the conductive patterns is less than or equal to half a length of the demarcation path segment.

4. The touch layer according to claim 1, wherein
the conductive pattern group includes at least one first conductive pattern, and the first conductive pattern is one of the conductive patterns; and
the first electrode block has a grid structure, and at least one first square point vacancy is provided along the demarcation path segment; and the first conductive pattern is disposed at the first square point vacancy.

5. The touch layer according to claim 4, wherein
the conductive pattern group includes at least one second conductive pattern, and the second conductive pattern is one of the conductive patterns; and
the second electrode block has a grid structure, and at least one second grid point vacancy is provided along the demarcation path segment; and the second conductive pattern is disposed at the second grid point vacancy.

6. The touch layer according to claim 5, wherein
in the conductive pattern group, the first conductive pattern and the second conductive pattern are same in number.

7. The touch layer according to claim 5, wherein
the demarcation path segment includes: a first section and a second section that surround the first finger portion and are opposite along a width direction of the first finger portion; and
the conductive pattern group includes M1 first conductive patterns distributed along the first section, and M2 second conductive patterns distributed along the second section, wherein M1 and M2 are both greater than or equal to 1.

8. (canceled)

9. The touch layer according to claim 7, wherein
at least one of the M1 first conductive patterns and at least one of the M2 second conductive patterns are opposite to each other along the width direction of the first finger portion.

10. The touch layer according to claim 7, wherein
the conductive pattern group further includes M3 second conductive patterns distributed along the first section, and M4 first conductive patterns distributed along the second section, wherein M3 and M4 are both greater than or equal to 1.

11. (canceled)

12. The touch layer according to claim 10, wherein
at least one of the M3 second conductive patterns is opposite to at least one of the M4 first conductive patterns along the width direction of the first finger portion.

13. The touch layer according to claim 5, wherein
the demarcation path segment includes: a third section surrounding the first finger portion and extending substantially along a width direction of the first finger potion, and a fourth section located between the two adjacent first finger potions, wherein
the conductive pattern group further includes N1 first conductive patterns distributed along the third section and N2 second conductive patterns distributed along the fourth section, N1 and N2 are both greater than or equal to 1;
and/or
the conductive pattern group further includes Q1 second conductive patterns distributed along the third section and Q2 first conductive patterns distributed along the fourth section, Q1 and Q2 are both greater than or equal to 1.

14. (canceled)

15. The touch layer according to claim 13, wherein
in a case where the conductive pattern group includes the N1 first conductive patterns and the N2 second conductive patterns,
at least one of the N1 first conductive patterns is distributed at an end of the third section; and
at least one of the N2 second conductive patterns is distributed at an end of the fourth section.

16. The touch layer according to claim 13, wherein
in a case where the conductive pattern group includes the Q1 second conductive patterns and the Q2 first conductive patterns,
at least one of the Q1 second conductive patterns is distributed at an end of the third section; and
at least one of the Q2 first conductive patterns is distributed at an end of the fourth section.

17. The touch layer according to claim 1, wherein
the first finger portion includes a first finger segment and a second finger segment, and the first finger segment is farther from the first body than the second finger segment; a width of the first finger segment is less than a width of the second finger segment.

18. The touch layer according to claim 17, wherein
the conductive pattern group includes: at least one conductive pattern distributed along a portion of the demarcation path segment surrounding the first finger segment;
and/or
the conductive pattern group includes at least one conductive pattern distributed along a portion of the demarcation path segment surrounding the second finger segment.

19. The touch layer according to claim 1, wherein
the first finger portion has a grid structure, wherein
along a width direction of the first finger portion, areas of two adjacent squares in the grid structure are not equal; and/or along an extension direction of the first finger portion, areas of two adjacent squares in the grid structure are not equal.

20. The touch layer according to claim 1, wherein
the first finger portion has a grid structure, wherein
the first finger portion has a first break, and the first break communicates two adjacent squares in the grid structure in a width direction of the first finger portion;
and/or
the first finger portion has a second break, and the second break communicates two adjacent squares in the grid structure in an extension direction of the first finger portion.

21. The touch layer according to claim 1, wherein
the first body is provided therein with a plurality of first dummy portions, and the first dummy portions are electrically insulated from the first electrode block;
and/or
the second electrode block is provided therein with a plurality of second dummy portions, and the second dummy portions are electrically insulated from the second electrode block.

22. A touch display apparatus, comprising:
a plurality of sub-pixels;
a pixel define layer, having a plurality of openings to define positions of the plurality of sub-pixels; and
the touch layer according to claim 1; in the touch layer, the first electrode blocks, the second electrode blocks and the conductive pattern group forming a grid structure, and the grid structure including a plurality of squares;
wherein the plurality of squares include at least one first square, and the first square is jointly surrounded by the first electrode block, the second electrode block, and the conductive pattern in the conductive pattern group, and the first square is directly opposite to an opening along a thickness direction of the touch layer.

23. A method for manufacturing a touch layer, comprising:
forming a first sensing electrode and a second sensing electrode that are arranged crosswise and insulated from each other, wherein the first sensing electrode includes a plurality of first electrode blocks electrically connected to each other; the second sensing electrode includes a plurality of second electrode blocks electrically connected to each other; a first electrode block includes a first body and a plurality of first finger portions protruding from the first body; and a second electrode block includes a plurality of notches located at an edge thereof, and a first finger portion extends into a notch; and
forming a conductive pattern group, wherein the conductive pattern group includes a plurality of conductive patterns distributed spaced apart along a demarcation path segment, the demarcation path segment is a portion, between root endpoints of two adjacent first finger portions at a same side, of a demarcation line between the first electrode block and the second electrode block; and a conductive pattern is jointly surrounded by the first electrode block and the second electrode block, and is insulated from both the first electrode block and the second electrode block.
